(19) United States
(12) Patent Application Publication
(10) Pub. No.: US 2011/0227639 A1
(43) Pub. Date: Sep. 22, 2011

(54) Method and Apparatus for Suppressing Bitline Coupling Through Miller Capacitance to a Sense Amplifier Interstitial Node

(75) Inventors: Michael ThaiThanh Phan, Cary, NC (US); Chiaming Chai, Chapel Hill, NC (US); Manish Garg, Morrisville, NC (US)

(73) Assignee: QUALCOMM Incorporated, San Diego, CA (US)

(21) Appl. No.: 12/727,833

(22) Filed: Mar. 19, 2010

(51) Int. Cl. G06G 7/00; H03F 3/45

(52) U.S. Cl. 327/563; 330/253

(57) ABSTRACT

A sense amplifier circuit is implemented for suppressing Miller effect capacitive coupling. The amplifier circuit comprises a differential amplifier circuit having a first input, a first output interstitial node, a second input, a second output interstitial node, a third input to enable or disable the differential amplifier, and having an equalizer circuit coupled between the first output interstitial node and the second output interstitial node. The amplifier circuit also comprises a cross coupled latch circuit having a first latch input coupled to the first output interstitial node, a second latch input coupled to the second output interstitial node, a first latch output, and a second latch output, wherein during a first time period the first latch output and the second latch output are precharged, the differential amplifier circuit is disabled, and the equalizer circuit is enabled to suppress the Miller effect capacitive coupling on the sense amplifier inputs.

### FIELD OF THE DISCLOSURE

The present disclosure relates generally to the field of memory arrays in integrated circuits and processing systems, and more specifically, to suppressing bitline coupling through Miller capacitance within a memory array sense amplifier.

### BACKGROUND

Many portable products, such as cell phones, laptop computers, netbook computers, personal data assistants (PDAs), portable television devices, or the like, utilize a processor executing programs, such as, operating system, communication, and multimedia programs. The processing system for such products includes a processor, a source of instructions, a source of input operands, and storage space for storing results of execution. For example, the instructions and input operands may be stored in a hierarchical memory configuration consisting of general purpose registers and multi-levels of caches, including, for example, an instruction cache, a data cache, and system memory. The functional complexity of such portable products, other personal computers, and the like, requires high performance processors and memory.

Internal to a processor complex, memory arrays and pipeline stages are designed to meet a worst case critical timing path corresponding to a desired clock frequency. Memory arrays may be required to operate at gigahertz (GHz) clock frequencies in order to meet a product's functional requirements. As metal oxide semiconductor (MOS) devices shrink smaller and smaller due to increasingly dense nanometer technologies, performance of memory cells generally is reduced due to parasitic capacitance in the smaller device sizes. Such parasitic capacitance and smaller device sizes are a function of the particular implementation and the technology process used to manufacture a device, and once a design is instantiated in silicon cannot be changed. For example, Miller effect capacitances are operative in the gate to drain of differential pair n-channel MOS FETs of a memory array sense amplifier having an effect that may potentially couple bitline input signals from a prior cycle to interstitial nodes which results in an effect to the performance of the sense amplifier. Thus, there is an increasing difficulty in memory array sense amplifiers meeting frequency requirements.

### SUMMARY

The present disclosure recognizes that improving performance of memory arrays and their associated sense amplifiers is important to portable applications and in general for improving performance in processing systems. To such ends, an embodiment of the invention addresses a sense amplifier circuit with Miller effect compensation. The sense amplifier circuit comprises a differential amplifier circuit having a first input, a first output interstitial node, a second input, a second output interstitial node, a third input to enable or disable the differential amplifier, and having an equalizer circuit coupled between the first output interstitial node and the second output interstitial node, wherein the Miller effect capacitive coupling is between the first input and the first output interstitial node and between the second input and the second output interstitial node. The sense amplifier circuit also comprises a cross coupled latch circuit having a first latch input coupled to the first output interstitial node, a second latch input coupled to the second output interstitial node, a first latch output, and a second latch output, wherein during a first time period the first latch output and the second latch output are precharged, the differential amplifier circuit is disabled, and the equalizer circuit is enabled to suppress the Miller effect capacitive coupling, prior to enabling and wherein during a second time period the differential amplifier circuit is enabled.

Another embodiment of the invention addresses a method of suppressing capacitive coupling of differential inputs in a first time period prior to reading a differential input signal in a second time period. In the first time period, disabling a differential amplifier circuit having a first input, a first output interstitial node, a second input, and a second output interstitial node. In the first time period, precharging a first latch output and a second latch output of a latch circuit, wherein a first latch input of the latch circuit is coupled to the first output interstitial node and a second latch input of the latch circuit is coupled to the second output interstitial node. In the first time period, equalizing a voltage difference between the first output interstitial node and the second output interstitial node, wherein the capacitive coupling is suppressed between the differential inputs and the first output interstitial node and the second output interstitial node. In the second time period, enabling the differential amplifier to read the differential input signal.

A further embodiment addresses a sense amplifier circuit for suppressing Miller effect bit line capacitive coupling. The sense amplifier circuit comprises a differential amplifier circuit having a true and a complement differential input, a first output interstitial node, a second output interstitial node, an amplifier control input to enable or disable the differential amplifier and having an equalizer circuit coupled between the first output interstitial node and the second output interstitial node, wherein the Miller effect capacitive coupling is between the true and complement differential input and the first output interstitial node and the second output interstitial node. The sense amplifier circuit also comprises a cross coupled latch circuit arrangement of four transistors having a latch first input, a latch first output, a latch second input, and a latch second output, the latch first input coupled to the first output interstitial node, the latch second input coupled to the second output interstitial node, wherein during a first time period the latch first output and the latch second output are precharged, the differential amplifier is disabled, and the equalizer circuit is enabled to suppress the Miller effect capacitive coupling prior to enabling the differential amplifier in a second time period.

It is understood that other embodiments of the present invention will become readily apparent to those skilled in the art from the following detailed description, wherein various embodiments of the invention are shown and described by way of illustration. As will be realized, the invention is capable of other and different embodiments and its several details are capable of modification in various other respects, all without departing from the present invention. Accordingly, the drawings and detailed description are to be regarded as illustrative in nature and not as restrictive.

### BRIEF DESCRIPTION OF THE DRAWINGS

FIG. 1 illustrates a wireless communication system in which an embodiment of the invention may be advantageously employed;

FIG. 2A shows a processor system employing sense amplifier circuits which suppress bit line coupling in accordance with the present invention;

FIG. 2B is a block diagram of a memory cell circuit suitable for use in various memory arrays;

FIG. 3 is a first sense amplifier circuit;

FIG. 4A is an exemplary embodiment of a second sense amplifier with Miller capacitance (Mcap) suppression circuit;

FIG. 4B is a third sense amplifier circuit with Miller capacitance (Mcap) suppression circuit;

FIG. 4C is an exemplary embodiment of a fourth sense amplifier with Miller capacitance (Mcap) suppression circuit;

FIG. 5A shows an illustrative timing diagram for read after write operation of the circuit of FIG. 4A;

FIG. 5B shows an illustrative timing diagram for a zoomed in view of a read after write operation of the circuit of FIG. 3;

FIG. 5C shows an illustrative timing diagram for a zoomed in view of a read after write operation of the circuit of FIG. 4A; and

FIG. 6 illustrates a process for reading a value stored in a memory cell using the second sense amplifier with Mcap suppression circuit of FIG. 4A.

### DETAILED DESCRIPTION

The present invention will now be described more fully with reference to the accompanying drawings, in which several embodiments of the invention are shown. This invention may, however, be embodied in various forms and should not be construed as limited to the embodiments set forth herein. Rather, these embodiments are provided so that this disclosure will be thorough and complete, and will fully convey the scope of the invention to those skilled in the art.

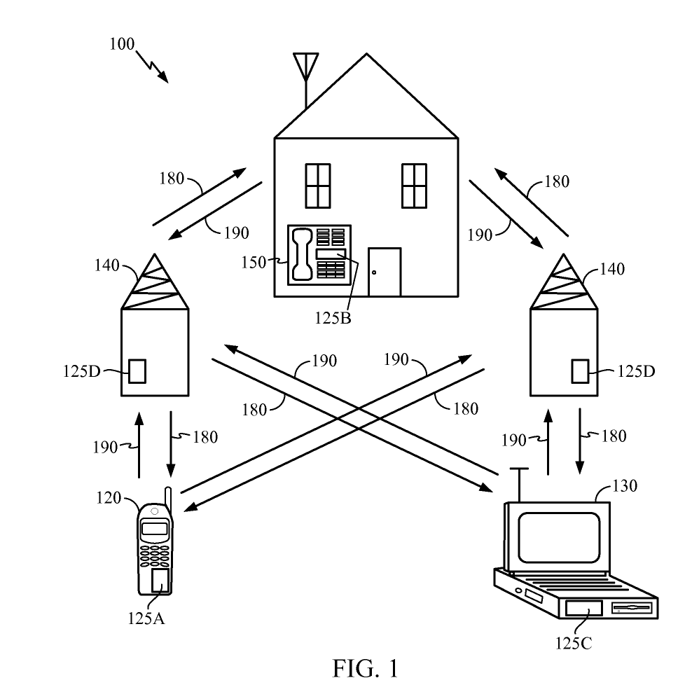

FIG. 1 illustrates an exemplary wireless communication system 100 in which an embodiment of the invention may be advantageously employed. For purposes of illustration, FIG. 1 shows three remote units 120, 130, and 150 and two base stations 140. It will be recognized that common wireless communication systems may have many more remote units and base stations. Remote units 120, 130, 150, and base stations 140 which include hardware components, software components, or both as represented by components 125A, 125C, 125B, and 125D, respectively, have been adapted to embody the invention as discussed further below. FIG. 1 shows forward link signals 180 from the base stations 140 to the remote units 120, 130, and 150 and reverse link signals 190 from the remote units 120, 130, and 150 to the base stations 140.

In FIG. 1, remote unit 120 is shown as a mobile telephone, remote unit 130 is shown as a portable computer, and remote unit 150 is shown as a fixed location remote unit in a wireless local loop system. By way of example, the remote units may alternatively be cell phones, pagers, walkie talkies, handheld personal communication system (PCS) units, portable data units such as personal data assistants, or fixed location data units such as meter reading equipment. Although FIG. 1 illustrates remote units according to the teachings of the disclosure, the disclosure is not limited to these exemplary illustrated units. Embodiments of the invention may be suitably employed in any system having memory arrays.

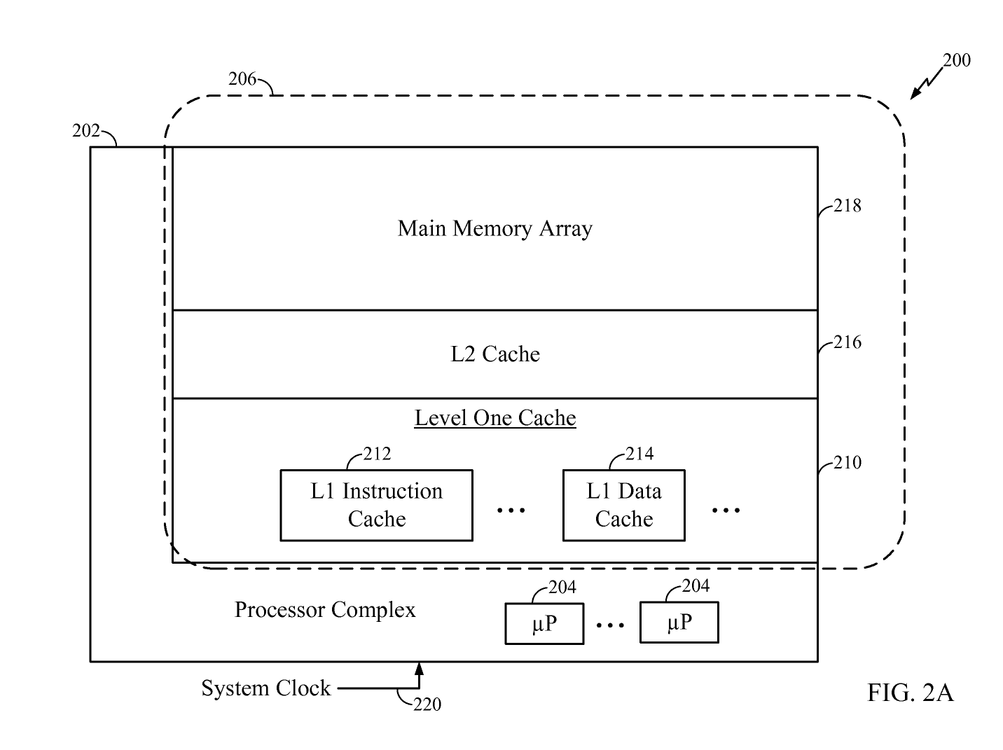

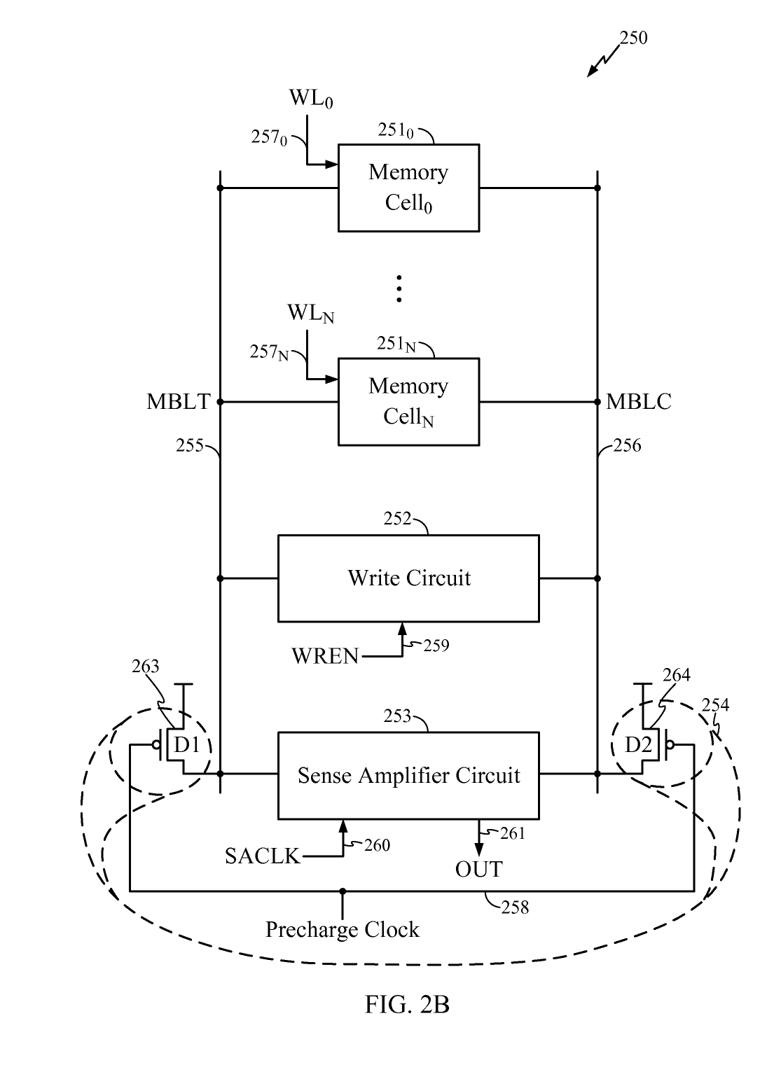

FIG. 2A shows a processor system 200 employing sense amplifier circuits which suppress bit line coupling in accordance with the present invention. The processor system 200 includes a processor complex 202 having one or more processors 204 and a hierarchical memory 206 having level one (L1) caches 210 with one or more L1 instruction caches 212 and one or more L1 data caches 214, a level 2 (L2) cache 216 and a memory array 218. Peripheral devices which may connect to the processor complex are not shown for clarity of discussion. The processor system 200 may include processors running at gigahertz clock frequencies and large capacity dense memories. The processor system 200 may be suitably employed in hardware components 125A-125D of FIG. 1 for executing program code that is stored in the hierarchical memory 206.

The various logic components of the processor system 200 may be implemented using application specific integrated circuit (ASIC) technology, field programmable gate array (FPGA) technology, or other programmable logic, discrete gate or transistor logic, or any other available technology suitable for an intended application.

FIG. 2B is a block diagram of a memory circuit 250 suitable for use in various memory arrays. The memory circuit 250 comprises memory cells 251₀ to 251_{N}, a write circuit 252, a sense amplifier circuit 253, and a precharge circuit 254. Each of the memory cells 251₀ to 251_{N} are coupled to a memory bit line true (MBLT) 255 and a memory bit line complement (MBLC) 256. When selected by one of the word lines WL₀ 257₀ to WL_{N} 257_{N}, each of the memory cells 251₀ to 251_{N} is adapted to alter the signals on the MBLT 255 and the MBLC 256 to provide a true and complement value of a data bit stored in a selected memory cell. The precharge circuit 254, utilizing PMOS devices D1 263 and D2 264, pulls up the MBLT 255 and MBLC 256 when a precharge clock 258 is low. The precharge clock 258 precedes an active write line signal, such as one of the WL₀ 257₀ to WL_{N} 257_{N} signals. A value to be stored in one of the memory cells 251₀ to 251_{N} is written when the appropriate memory cell is selected by the desired word line WL₀ 257₀ to WL_{N} 257_{N} and a write enable (WREN) signal 259 is asserted to the write state. A stored memory cell value may be read when the memory cell is selected by one of the word lines WL₀ 257₀ to WL_{N} 257_{N} and a sense amplifier clock (SACLK) 260 is asserted to the read state producing out signal 261. Out signal 261 may also be presented in a true and complement form as described in more detail below.

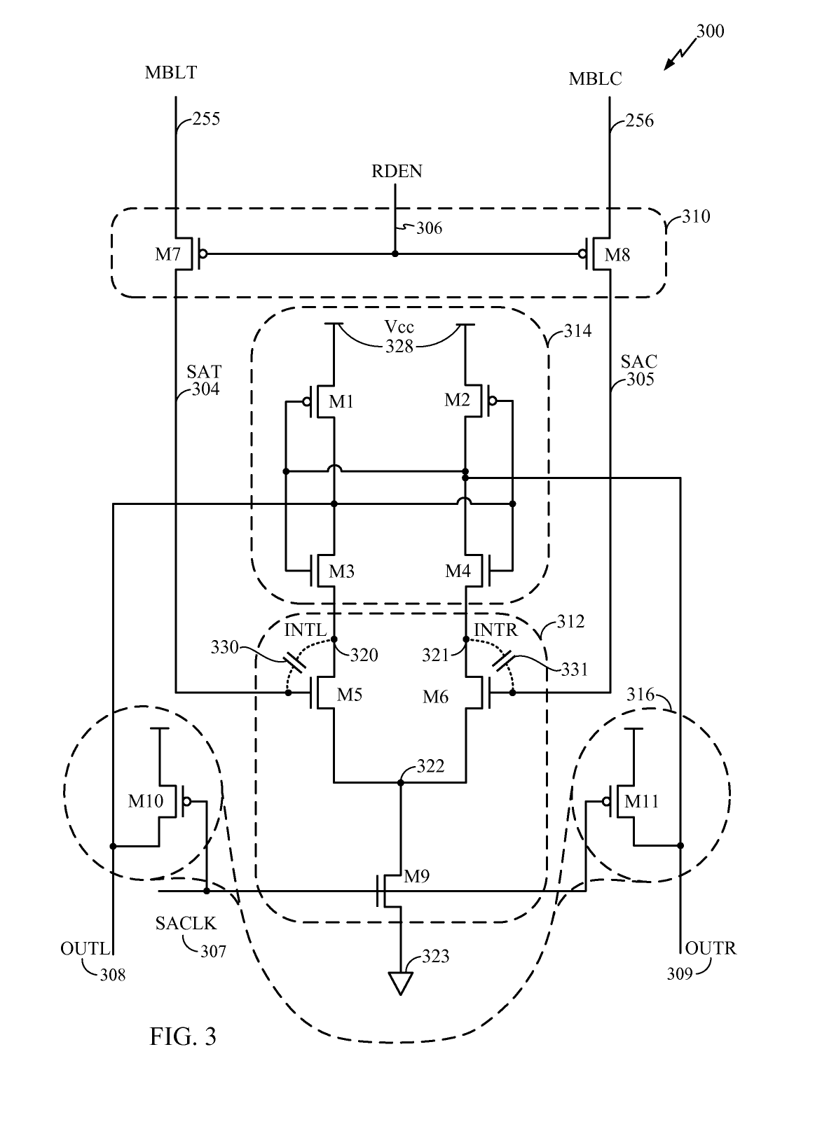

FIG. 3 shows a first sense amplifier circuit 300. The first sense amplifier circuit 300 comprises a bit switch circuit 310, a differential amplifier circuit 312, a cross coupled latch circuit 314, and a precharge circuit 316. The bit switch circuit 310 comprises PMOS devices M7 and M8. The differential amplifier circuit 312 comprises NMOS devices M5, M6, and M9. The cross coupled latch circuit 314 comprises PMOS devices M1 and M2 and NMOS devices M3 and M4. The precharge circuit 316 comprises PMOS devices M10 and M11. The first sense amplifier circuit 300 also comprises the memory bit line true (MBLT) 255, the memory bit line complement (MBLC) 256, read enable (RDEN) 306, sense amplifier clock (SACLK) 307, first output OUTL 308, and second output OUTR 309.

The bit switch circuit 310 controllably connects output values from a selected memory cell on the memory bit lines MBLT 255 and MBLC 256 coupled to sense amplifier true (SAT) input 304 and sense amplifier complement (SAC) input 305, respectively, when the RDEN 306 is asserted low. When the RDEN 306 is high, MBLT 255 and MBLC 256 are disconnected from the inputs to the differential amplifier circuit 312. The SAT input 304 is connected to the gate of M5 and the SAC input 305 is connected to the gate of M6. The source and drain of M5 are connected between an interstitial node left (INTL) 320 that is a first output of the differential amplifier circuit 312 and connection point 322, respectively. The source and drain of M6 are connected between an interstitial node right (INTR) 321 that is a second output of the differential amplifier circuit 312 and the connection point 322, respectively. The source and drain of M9 are connected between the connection point 322 and ground 323, respectively, and M9 is turned on when a high level assertion of the SACLK 307 is applied to the gate of M9. The first output INTL 320 and second output INTR 321 are outputs of the differential amplifier circuit 312 that are connected to inputs of the cross coupled latch circuit 314.

In the cross coupled latch circuit 314, the gate input of M1 is connected to OUTR 309 and the source and drain of M1 are connected to Vcc 328 and OUTL 308, respectively. The input gate of M2 is connected to OUTL 308 and the source and drain of M2 are connected to Vcc 328 and OUTR 309, respectively. The input gate of M3 is connected to OUTR 309 and the source and drain of M3 are connected to OUTL 308 and the first output interstitial node INTL 320, respectively. The input gate of M4 is connected to OUTL 308 and the source and drain of M4 are connected to OUTR 309 and the second output interstitial node INTR 321, respectively.

The precharge circuit 316 has pullup devices M10 and M11 which precharge the output signals OUTL 308 and OUTR 309 prior to reading a value from a memory cell. The precharge circuit 316 is active when the SACLK 307 is asserted low. When the pullup devices M10 and M11 are turned off due to a high level assertion of the SACLK 307, the precharge circuit 316 is disabled from precharging.

In order to read a bit from a memory cell, the first sense amplifier circuit 300 first precharges the cross coupled latch outputs OUTL 308 and OUTR 309 followed by asserting the read enable RDEN 306. Thus, the selected memory cell outputs MBLT 255 and MBLC 256 are passed to the SAT input 304 and SAC input 305 of the differential amplifier circuit 312, respectively. Next the precharge circuit 316 is disabled with SACLK 307 asserted high which also enables the differential amplifier circuit 312. The cross coupled latch circuit 314 latches the amplified input signals providing the outputs OUTL 308 and OUTR 309 as logic level outputs representing the value stored in the selected memory cell. For the cross coupled latch circuit 314 to successfully latch the outputs of the differential amplifier circuit 312, there must be a sufficient voltage difference between the signals SAT 304 and SAC 305 before the SACLK 307 is asserted high.

Also, in the first sense amplifier circuit 300, Miller effect capacitors 330 and 331, shown with dotted line connections, may have an effect on the interstitial node INTL 320 or INTR 321 due to coupling of the MBLT 255 or MBLC 256 after a write operation. For example, during a write operation, either the MBLT 255 or MBLC 256 is driven low from a write 0 or a write 1 operation to selected memory cells. After the write operation is completed, MBLT 255 and MBLC 256 are precharged high. The coupling effect may be limited in this first sense amplifier circuit 300 depending on whether RDEN 306 is asserted early when the write bitline precharge operation is still operative. When the RDEN 306 is asserted, both the M7 PMOS device and M8 PMOS device are enabled to conduct. Thus, either the MBLT 255 or MBLC 256 may couple to the interstitial nodes, INTL 320 INTR 321, through Miller capacitors 330 and 331. Since this Miller effect coupling effect creates a voltage offset between INTL 320 and INTR 321, a read operation after this write operation is affected. For example, the offset voltage may effectively decrease the gain of the first sense amplifier 300. As a result, the first sense amplifier circuit 300 may require a larger differential voltage between SAT 304 and SAC 305 to provide reliable read sensing. In such a case, the SACLK 307 has increased duration which degrades performance.

In an exemplary 45 nanometer (nm) technology, a memory read operation in the first sense amplifier circuit 300 has a differential voltage requirement between the MBLT 255 and MBLC 256 of 210 mV and between SAT 304 and SAC 305 of 170 mV due to a voltage loss from the bit switch circuit 310. The 210 mV and 170 mV values are based on worst case process, voltage, and temperature variations. The loss of sense amplifier sensing margin due to the bit switch circuit 310 is 210 mV−170 mV=40 mV. Sensing margin is also lost due to the bitline coupling to the interstitial nodes of the sense amplifier corresponding to an additional loss of 40 mV. This is an overall loss of 80 mV that corresponds to 120 picoseconds of sense amplifier timing in the 45 nm technology. As a result, the first sense amplifier circuit 300 timing may not meet overall chip timing required for a desired gigahertz clock frequency at the worst case operating conditions.

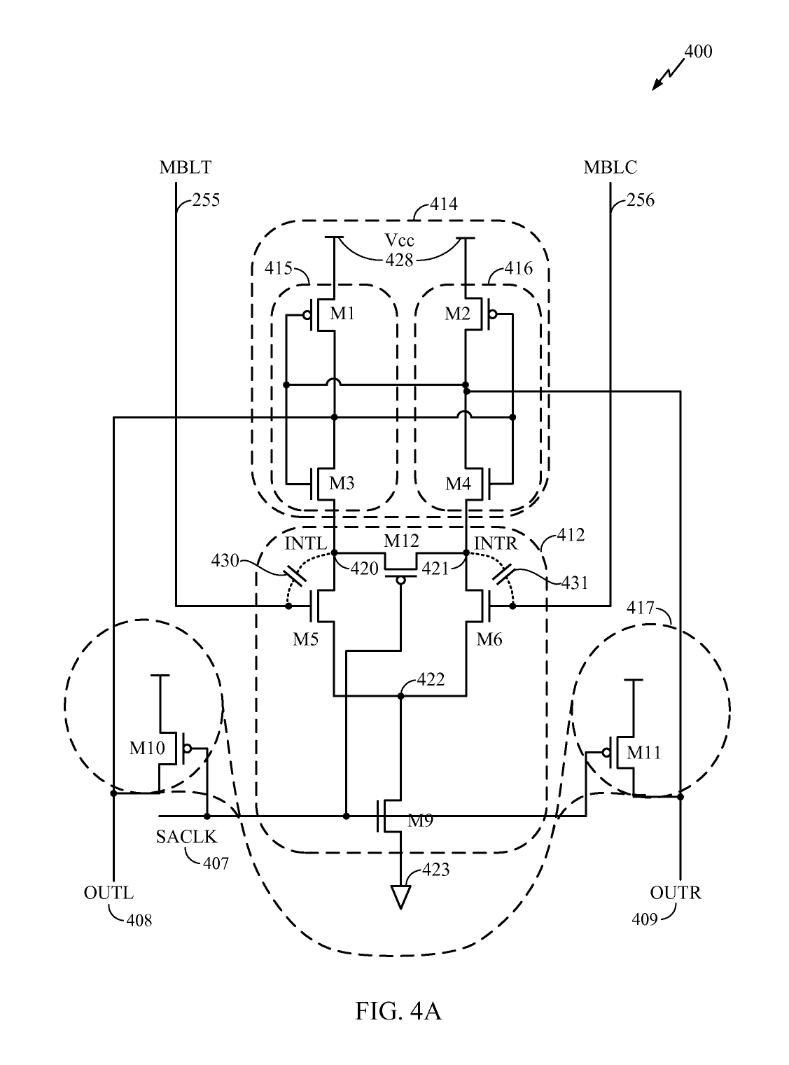

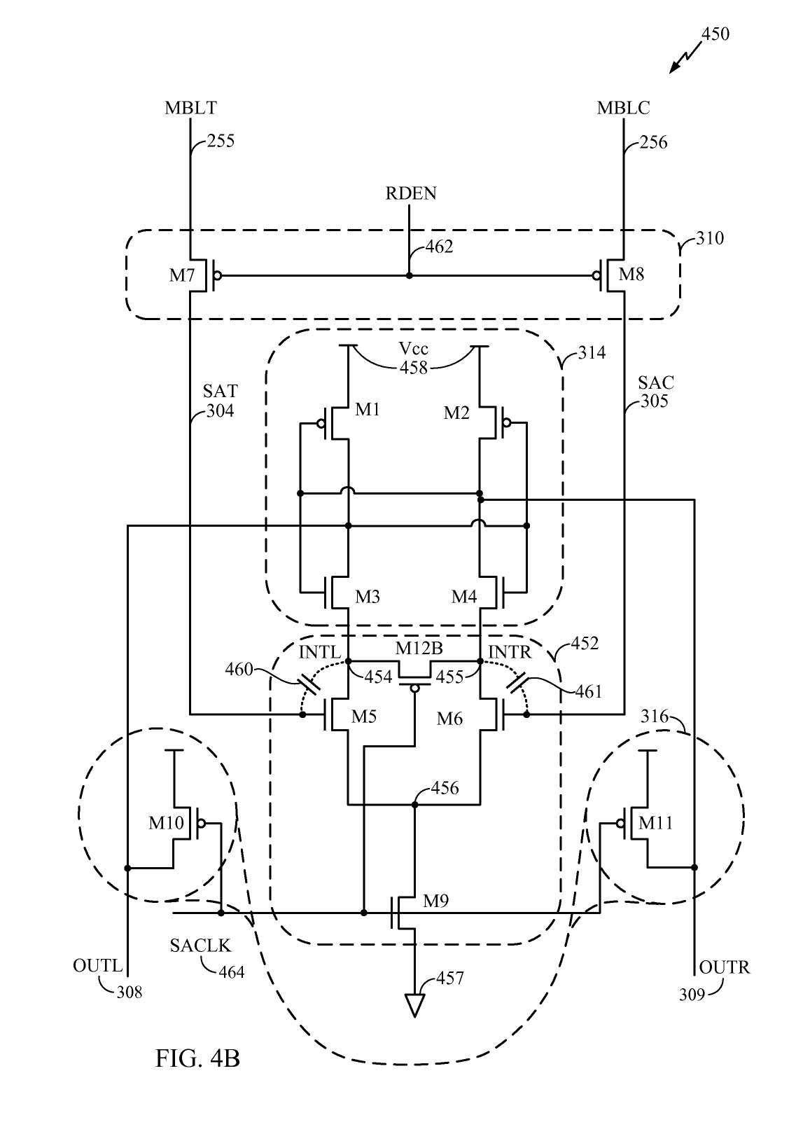

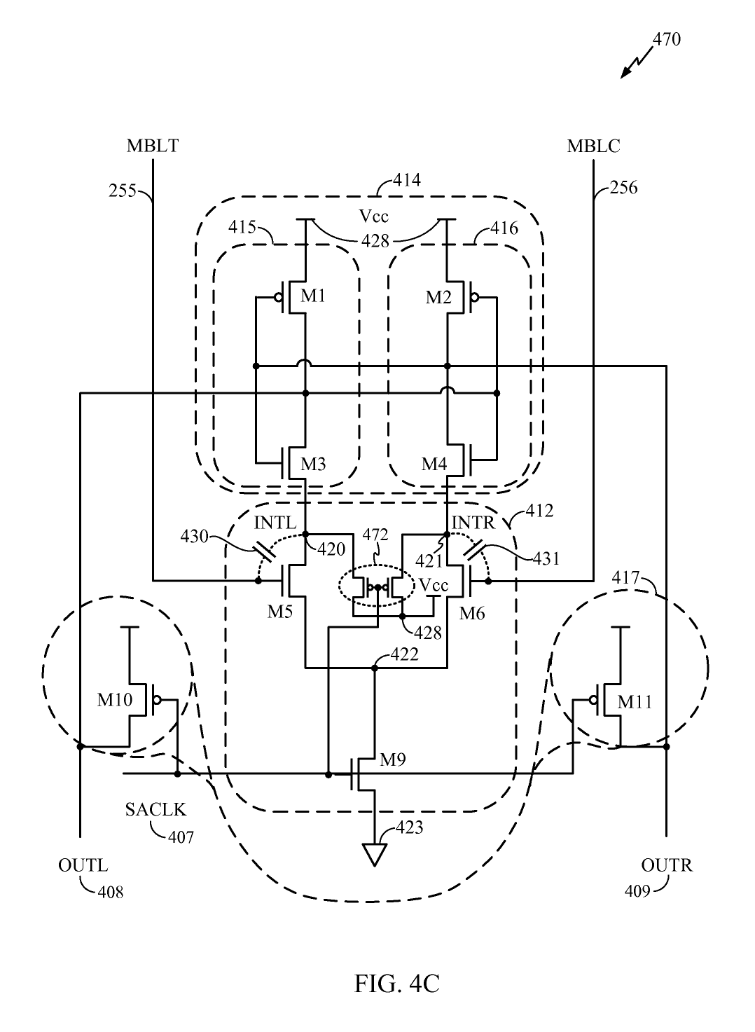

FIG. 4A is an exemplary embodiment of a second sense amplifier sense amplifier with Miller capacitance (Mcap) suppression circuit 400 which suppresses bit line coupling in accordance with the present invention. The second sense amplifier with Mcap suppression circuit 400 comprises a differential amplifier circuit 412, a cross coupled latch circuit 414, and a precharge circuit 417. The differential amplifier circuit 412 comprises NMOS devices M5, M6, M9, and a PMOS equalizer circuit device M12. The cross coupled latch circuit 414 comprises a first stack 415 of two complementary transistors and a second stack 416 of two complementary transistors. The first stack 415 comprises a PMOS device M1 and an NMOS device M3 and the second stack 416 comprises PMOS device M2 and NMOS device M4. The precharge circuit 417 comprises PMOS devices M10 and M11. The second sense amplifier with Mcap suppression circuit 400 also comprises memory bit line true (MBLT) 255, memory bit line complement (MBLC) 256, sense amplifier clock (SACLK) 407, first output OUTL 408, and second output OUTR 409.

The second sense amplifier with Mcap suppression circuit 400 directly connects output values from a selected memory cell on the memory cell bit lines MBLT 255 and MBLC 256 to the gates of M5 and M6, respectively, of the differential amplifier circuit 412. It is noted that direct coupling of the memory cell bit signals to the inputs of the differential amplifier circuit 412 does not require the use of a bit switch circuit, such as the bit switch circuit 310 of FIG. 3. The source and drain channel terminals of M5 are connected between an interstitial node left (INTL) 420 that is a first output of the differential amplifier circuit 412 and connection point 422, respectively. The source and drain channel terminals of M6 are connected between an interstitial node right (INTR) 421 that is a second output of the differential amplifier circuit 412 and the connection point 422, respectively. The source and drain channel terminals of M9 are connected to the connection point 422 and ground 423, respectively. M9 is turned on when a high level assertion of the SACLK 407 is applied to the gate of M9. The first output INTL 420 and second output INTR 421 are outputs of the differential amplifier circuit 412 that are connected to inputs of the cross coupled latch circuit 414. The source and drain of the equalizer circuit device M12 are connected to the first output INTL 420 and second output INTR 421, respectively. M12 is turned on when a low level assertion of the SACLK 407 is applied to the gate of the equalizer circuit device M12 and M12 is off otherwise. It is appreciated that an NMOS equalizer circuit device may be used as an alternative implementation of the equalizer circuit device M12 with, for example, an inverted SACLK signal applied to the gate of the NMOS equalizer circuit device.

In the cross coupled latch circuit 414, the gate input of M1 is connected to OUTR 409 and the source and drain of M1 are connected to Vcc 428 and OUTL 408, respectively. The input gate of M2 is connected to OUTL 408 and the source and drain of M2 are connected to Vcc 428 and OUTR 409, respectively. The input gate of M3 is connected to OUTR 409 and the source and drain of M3 are connected to OUTL 408 and the first output interstitial node INTL 420, respectively. The input gate of M4 is connected to OUTL 408 and the source and drain of M4 are connected to OUTR 409 and the second output interstitial node INTR 421, respectively.

The precharge circuit 417 has pullup devices M10 and M11 which precharge the output signals OUTL 408 and OUTR 409 prior to reading a value from a memory cell. The precharge circuit 417 is active when the SACLK 407 is asserted low while the differential amplifier circuit 412 is disabled. When M9 is turned on due to a high level assertion of the SACLK 407, the precharge circuit 417 is disabled from precharging.

In order to read a bit from a memory cell, the second sense amplifier with Mcap suppression circuit 400 first precharges the cross coupled latch outputs OUTL 408 and OUTR 409 with SACLK 407 asserted low. A memory cell word line is asserted. This step is followed by disabling the precharge circuit 416 with SACLK 407 asserted high which enables the differential amplifier circuit 412 to amplify the selected memory cell outputs applied to the inputs of the differential amplifier circuit 412. The cross coupled latch circuit 414 latches the amplified input signals providing logic level output signals on OUTL 408 and OUTR 409 that represent the value stored in the selected memory cell. For the cross coupled latch circuit 414 to successfully latch the output of the differential amplifier circuit 412, the voltage difference between the MBLT 255 and the MBLC 256 must be at threshold level to reliably store the amplified signal in the cross coupled latch circuit 414. For performance reasons, the voltage difference should reach the threshold level before the SACLK 407 is asserted high.

Miller effect capacitors 430 and 431, shown with dotted line connections, may have an effect on the interstitial node INTL 420 or INTR 421 due to coupling of the MBLT 255 or MBLC 256 after a write operation. For example, during a write operation, either the MBLT signal 255 or MBLC signal 256 is driven low from a write 0 or a write 1 operation to selected memory cells. After the write operation is completed, MBLT 255 and MBLC 256 are precharged high. During the bitline precharge, either MBLT 255 or MBLC 256 may couple to the interstitial nodes, INTL 420 INTR 421, thru Miller capacitors 430 and 431. Since this Miller coupling effect creates a voltage offset between INTL 420 and INTR 421, a read operation after this write operation is affected. For example, the offset voltage may effectively decrease the gain of the second sense amplifier 400. As a result, the second sense amplifier 400 may require a larger differential voltage between MBLT 255 and MBLC 256 to provide reliable read sensing. To mitigate the effect of the Miller effect capacitors 430 and 431, the equalizer circuit device M12 is turned on during the precharge operation when the SACLK 407 is asserted low. The equalizer circuit device M12 removes any differential voltage at the interstitial nodes INTL 420 and INTR 421 during a precharge time period. Thus, the equalizer circuit device M12 effectively removes an impeding effect the Miller effect capacitors 430 and 431 would otherwise have and advantageously improves the performance of the differential amplifier.

A bit switch circuit, such as the bit switch circuit 310 of FIG. 3, is not required in the second sense amplifier with Mcap suppression circuit 400 of FIG. 4A. In comparing the performance of the second sense amplifier with Mcap suppression circuit 400 with the performance of the first sense amplifier circuit 300 of FIG. 3, the delay associated with the bit switch circuit 310 is not present in the second sense amplifier with Mcap suppression circuit 400. Also, the voltage loss associated with the bit switch circuit is absent allowing a lower level voltage differential for reliable latching in the cross coupled latch circuit 414. Also, the addition of the equalizer circuit device M12 mitigates bit line coupling effects, for example, due to Miller effect coupling in write before read operations, which improves the differential voltage signal integrity. It is noted that other sources of noise could affect the differential voltage between the interstitial nodes INTL 420 and INTR 421, such as interconnect coupling noise. In these other such cases, the equalizer circuit device M12 of FIG. 4A or the equalizer circuit 472 of FIG. 4C, as described in more detail below, would provide improved tolerance to those sources of noise as well. This may allow the differential voltage to be further reduced.

In an exemplary 45 nanometer (nm) technology, a memory read operation in the first sense amplifier circuit 300 has a differential voltage requirement between the MBLT 255 and MBLC 256 of 210 mV and between SAT 304 and SAC 305 of 170 mV worst case as described above. The 210 mV represents a sufficient differential voltage level to be reliably latched in the cross coupled latch circuit 314. In the second sense amplifier with Mcap suppression circuit 400 having the equalizer circuit device M12, the 210 mV differential voltage has been reduced to a latch threshold that is the voltage required to reliably latch the first memory bit signal in the cross coupled latch. For example, 130 mV is a suitable latch threshold for a 45 nm technology under worst case process, voltage, and temperature variations. For performance reasons, the latch threshold is reached by the time the SACLK 407 is asserted high. In the present invention, each 40 mV improvement in the differential voltage difference represents a 60 picosecond (ps) improvement in memory array access time. Thus, the second sense amplifier with Mcap suppression circuit 400 achieves an 80 mV improvement in differential voltage which supports a 120 ps improvement, for example, in performance at the worst case operating conditions.

It is recognized that the equalizer circuit device M12 of the second sense amplifier with Mcap suppression circuit 400 of FIG. 4A may be used with the first sense amplifier circuit 300 of FIG. 3 to implement a third sense amplifier circuit 450 of FIG. 4B. The third sense amplifier circuit 450 comprises the bit switch circuit 310, a differential amplifier 452, the cross coupled latch 314, and the precharge circuit 316. The differential amplifier 452 includes an equalizer circuit device M12B coupled between interstitial nodes INTL 454 and INTR 455 to equalize the effects, for example, of Miller capacitance 460 and 461. In such the third sense amplifier circuit 450, the RDEN signal 462 may be enabled for a read cycle prior to the end of a write cycle and during a read of a selected memory bit cell and in such operation, the equalizer circuit device M12B may improve performance of a read access as compared to the first sense amplifier circuit 300. For example, the SACLK 464 may be asserted earlier in the read cycle due to the use of the equalizer circuit device M12B.

FIG. 4C is an exemplary embodiment of a fourth sense amplifier with Miller capacitance (Mcap) suppression circuit 470 which suppresses bit line coupling in accordance with the present invention. The fourth sense amplifier with Mcap suppression circuit 470 is similar to the second sense amplifier with Mcap suppression circuit 400 of FIG. 4A except for replacing the equalizer circuit device M12 with a two PMOS transistor equalizer circuit 472. The equalizer circuit 472 precharges the nodes INTL 420 and INTR 421 to Vcc 428. The two PMOS transistors are turned on when a low level assertion of the SACLK 407 is applied to the gates of the two PMOS transistors with the equalizer circuit 472 off otherwise. It is appreciated that a two NMOS transistor equalizer circuit may be used as an alternative implementation of the equalizer circuit 472 with, for example, an inverted SACLK signal applied to the gates of the two NMOS transistors. The equalizer circuit 472 removes any differential voltage at the interstitial nodes INTL 420 and INTR 421 during the precharge time period.

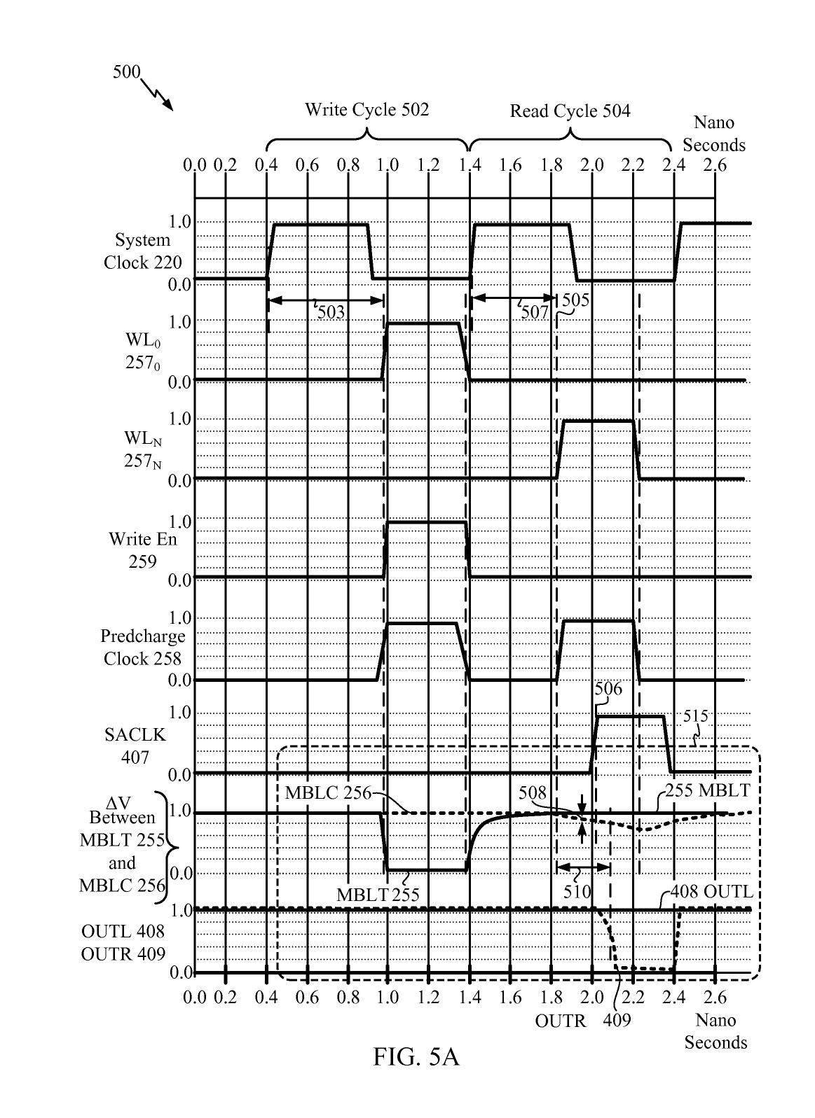

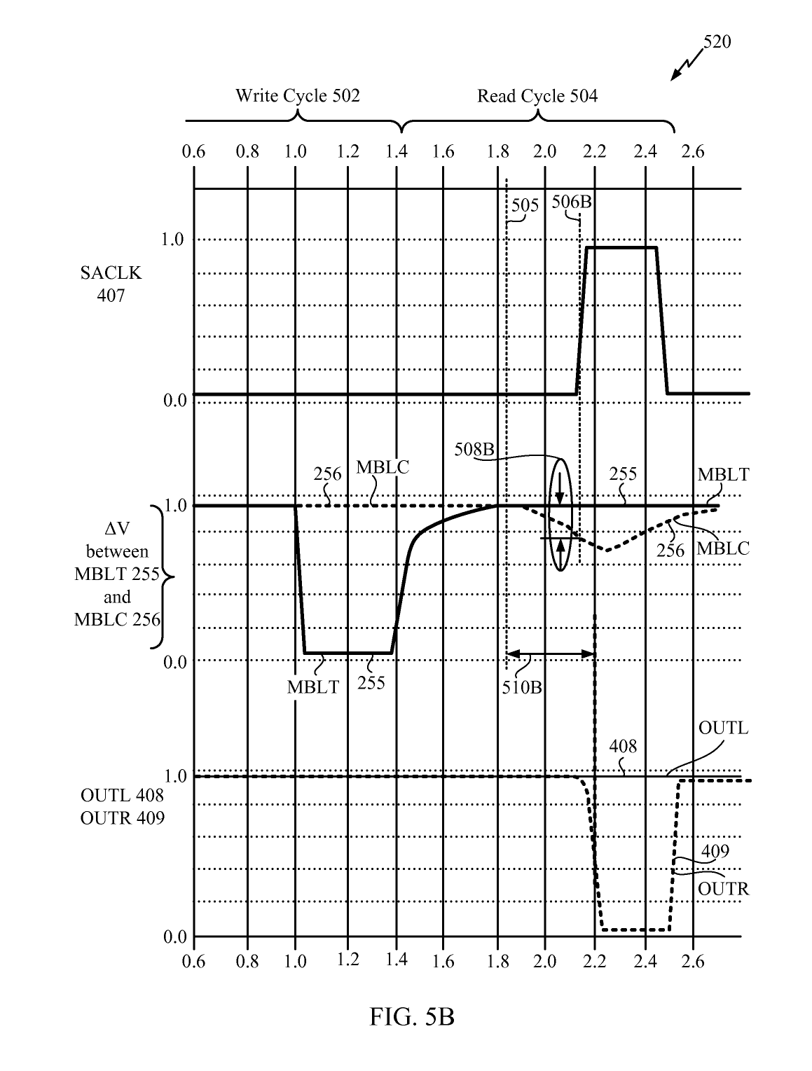

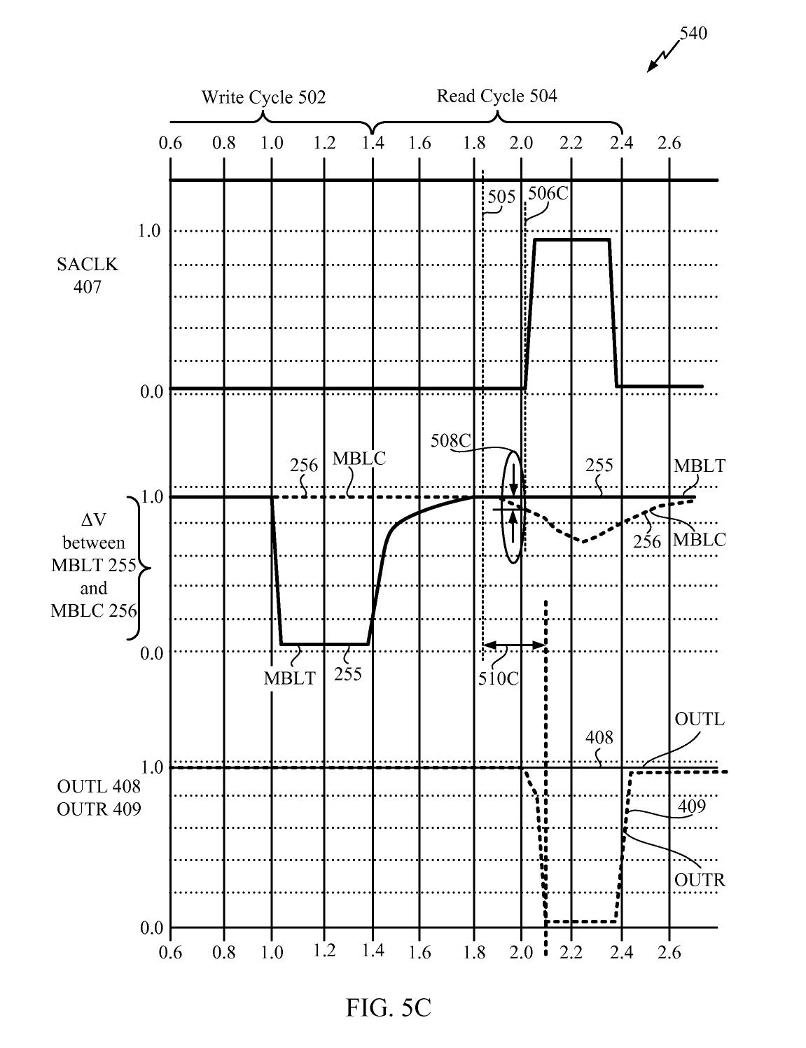

FIG. 5A illustrates a timing diagram 500 for operation of the second sense amplifier with Mcap suppression circuit 400 of FIG. 4A in accordance with the present invention. The second sense amplifier with Mcap suppression circuit 400 is coupled to the exemplary memory cells 251₀ to 251_{N} of FIG. 2B. Exemplary relationships between the timing events of FIG. 5A and the elements of FIG. 2B and FIG. 4A are indicated by referring to exemplary elements from the memory cell circuit 250 and from the second sense amplifier with Mcap suppression circuit 400 which may suitably be employed to carry out the timing events of FIG. 5A. A timing event is considered to occur when a signal transition crosses the particular threshold of a circuit used in an implementation technology. The system clock 220 defines the cycle time and operating frequency of the processor system 200. Other signals, such as the WLi 257i, Write EN 259, Precharge Clock 258, SACLK 407, MBLT 255, MBLC 256, OUTL 408, and OUTR 409, are related to the rising edges of system clock 220, by logic generation delays 503 and 507, which may vary in different implementations, for example.

For example, logic circuits described herein are assumed to respond to input signals at 30% of a ground level and below or 70% of a supply voltage level and above. For example, a logic “0” value would be considered anything less than or equal to 0.3 volts and a logic “1” value would be considered anything greater than or equal to 0.7 volts for a supply voltage of 1.0 volts. Depending upon technology, a different supply voltage may be used and a response tolerance different than 30% and 70% may also be used. The MBLT 255 and MBLC 256 from a selected memory cell are low voltage differential signals that are amplified and latched as described herein. A supply voltage of 1 volt is assumed in the timing diagram 500. It is noted that the rising and falling edges of the SACLK 407, and other signals may vary with voltage, process technology, and other factors such as signal loading. These variations may be accounted for by appropriate signal analysis techniques such as the use of analog circuit simulation techniques.

In FIG. 5A, during a write cycle 502, a zero is written to a memory cell, such as memory cell₀ 251₀ associated with word line WL₀ 257₀ of FIG. 2B. During the write cycle 502, WL₀ 257₀ and the write enable signal 259 are asserted high and the precharge is removed by the precharge clock 258 asserted high. The MBLT 255 is driven low and MBLC 256 remains high during the write cycle 502. The second sense amplifier with Mcap suppression circuit 400 is disabled with the SACLK 407 held low. Following the write cycle 502 is a read cycle 504 when a one is read from a different memory cell, such as memory cell_{N} 251_{N} associated with WL_{N} 257_{N}. During the read cycle 504, WL_{N} 257_{N} is asserted high and the precharge is removed by the precharge clock 258 being asserted high. With the precharge removed and WL_{N} 257_{N} asserted high, the MBLT 255 and MBLC 256 begin, at timing marker 505, to track the state of the memory cell_{N} which in this example holds a one value. At timing marker 506, the MBLT 255 and MBLC 256 achieve an adequate voltage differential 508, for example, a threshold of 130 mV. The SACLK 407 is then asserted high, removing the sense amplifier precharge and enabling the differential amplifier circuit 412. The 130 mV differential threshold voltage is an 80 mV improvement over the first sense amplifier circuit 300. The OUTL 408 and OUTR 409 of the cross coupled latch circuit 414 switch according to the state input to the differential amplifier circuit 412. The 80 mV improvement results in a 120 ps improvement in the read access time 510.

FIG. 5B shows an illustrative timing diagram for a zoomed in view of a read after write operation of the circuit of FIG. 3. Section 515 of FIG. 5A is zoomed in and the timing is adjusted to be representative of the first sense amplifier circuit 300. Timing marker 505 of FIG. 5A is used as a reference point. At timing marker 506B of FIG. 5B, MBLT 255 and MBLC 256 achieve an adequate voltage differential 508B, for example, a threshold of 210 mV. The SACLK 307 is then asserted high, removing the sense amplifier precharge and enabling the differential amplifier circuit 312. The OUTL 308 and OUTR 309 of the cross coupled latch circuit 314 switch according to the state input to the differential amplifier circuit 312, showing read access time 510B.

FIG. 5C shows an illustrative timing diagram for a zoomed in view of a read after write operation of the circuit of FIG. 4A. Section 515 of FIG. 5A is zoomed in and the timing is representative of the second sense amplifier circuit 400. Timing marker 505 of FIG. 5A is used as a reference point. At timing marker 506C of FIG. 5C, MBLT 255 and MBLC 256 achieve an adequate voltage differential 508C, for example, a threshold of 130 mV, which is an improvement of 80 mV over the voltage differential 508B. The SACLK 407 is then asserted high, removing the sense amplifier precharge and enabling the differential amplifier circuit 412. The 130 mV differential threshold voltage is an 80 mV improvement over the first sense amplifier circuit 300. The OUTL 408 and OUTR 409 of the cross coupled latch circuit 414 switch according to the state input to the differential amplifier circuit 412. The 80 mV improvement results in a 120 ps improvement in the read access time 510C as compared to the read access time 510B.

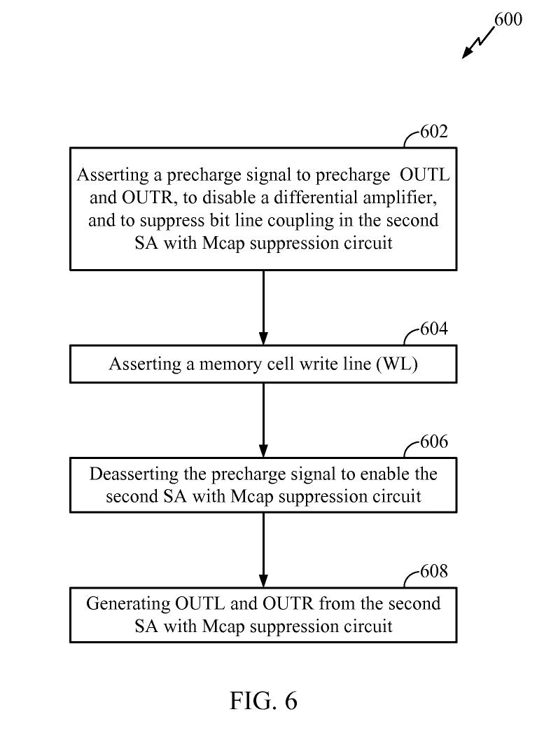

FIG. 6 shows a process 600 for reading a value stored in a memory cell using the second sense amplifier with Mcap suppression circuit 400, in accordance with the present invention. The process 600 starts at block 602 with asserting a precharge signal to precharge OUTL 408 and OUTR 409, to disable a differential amplifier, and to suppress bit line coupling in the second sense amplifier with Mcap suppression circuit 400. At block 604, the a memory cell word line (WL) is asserted. At block 606, the precharge signal is deasserted to enable the second sense amplifier with Mcap suppression circuit 400. At block 608, the OUTL 308 and OUTR 409 are generated from the second sense amplifier with Mcap suppression circuit 400.

While the invention is disclosed in the context of a processing system, it will be recognized that a wide variety of implementations, such as using bipolar transistors and implementing state machine functions having memory arrays with associated sense amplifiers may be employed using the techniques of the invention by persons of ordinary skill in the art consistent with the above discussion and the claims which follow.

What is claimed is:

1. A sense amplifier circuit with Miller effect compensation, the sense amplifier circuit comprising:
a differential amplifier circuit having a first input, a first output interstitial node, a second input, a second output interstitial node, a third input to enable or disable the differential amplifier, and having an equalizer circuit coupled between the first output interstitial node and the second output interstitial node, wherein the Miller effect capacitive coupling is between the first input and the first output interstitial node and between the second input and the second output interstitial node; and
a cross coupled latch circuit having a first latch input coupled to the first output interstitial node, a second latch input coupled to the second output interstitial node, a first latch output, and a second latch output, wherein during a first time period the first latch output and the second latch output are precharged, the differential amplifier circuit is disabled, and the equalizer circuit is enabled to suppress the Miller effect capacitive coupling, and wherein during a second time period the differential amplifier circuit is enabled.

2. The sense amplifier circuit of claim 1, wherein the first input is directly coupled to a memory bit cell first output providing a first memory bit signal representing a value stored in a selected memory bit cell and the second input is directly coupled to a second output of the memory bit cell providing a second memory bit signal representing a complement of the first memory bit signal.

3. The sense amplifier circuit of claim 2 wherein during the second time period a difference between the first memory bit signal and the second memory bit signal is amplified until the difference reaches a voltage required to reliably latch the first memory bit signal in the cross coupled latch.

4. The sense amplifier circuit of claim 1 wherein the equalizer circuit comprises:
a device with equalizer channel terminals coupled between the first output interstitial node and the second output interstitial node and with an equalizer control input, wherein the equalizer circuit is enabled while the differential amplifier circuit is disabled and the equalizer circuit is disabled while the differential amplifier circuit is enabled.

5. The sense amplifier circuit of claim 1, wherein the differential amplifier circuit further comprises:
a first device with first channel terminals coupled between the first output interstitial node and a connection point and with a first control input coupled to the first input;
a second device with second channel terminals coupled between the second output interstitial node and the connection point and with a second control input coupled to the second input; and
a third device with third channel terminals coupled between the connection point and a reference voltage and with a third control input connected to the third input.

6. The sense amplifier circuit of claim 1, wherein a bit switch circuit is coupled to the differential amplifier and to a group of selectable memory bit cells that share a memory bit cell first output providing a first memory bit signal representing a value stored in a selected memory bit cell and share a memory bit cell second output providing a second memory bit signal that is a complement of the first memory bit signal, the bit switch circuit having a first switch input coupled to the memory bit cell first output, a second switch input coupled to the memory bit cell second output, a first switch output coupled to the first input, and a second switch output coupled to the second input.

7. The sense amplifier circuit of claim 6, wherein the bit switch circuit connects the first memory bit signal to the first input and connects the second memory bit signal to the second input prior to the end of a write cycle and during a read of a selected memory bit cell.

8. The sense amplifier circuit of claim 1, wherein the equalizer circuit comprises:
a first device with first equalizer channel terminals coupled between the first output interstitial node and a reference voltage and with a first equalizer control input; and
a second device with second equalizer channel terminals coupled between the second output interstitial node and the reference voltage and with a second equalizer control input connected to the first equalizer control input, wherein the equalizer circuit is enabled while the differential amplifier circuit is disabled and the equalizer circuit is disabled while the differential amplifier is enabled.

9. A method of suppressing capacitive coupling of differential inputs in a first time period prior to reading a differential input signal in a second time period, the method comprising:
in the first time period, disabling a differential amplifier circuit having a first input, a first output interstitial node, a second input, and a second output interstitial node;
in the first time period, precharging a first latch output and a second latch output of a latch circuit, wherein a first latch input of the latch circuit is coupled to the first output interstitial node and a second latch input of the latch circuit is coupled to the second output interstitial node;
in the first time period, equalizing a voltage difference between the first output interstitial node and the second output interstitial node, wherein the capacitive coupling is suppressed between the differential inputs and the first output interstitial node and the second output interstitial node; and
in the second time period, enabling the differential amplifier to read the differential input signal.

10. The method of claim 9 further comprises:
enabling an equalizer circuit to equalize the voltage difference in response to a control signal received at an equalizer control input of an equalizer transistor with equalizer channel terminals coupled between the first output interstitial node and the second output interstitial node while the differential amplifier is disabled; and
disabling the equalizer circuit while the differential amplifier is enabled.

11. The method of claim 9 further comprises:
receiving a first memory bit signal at the first input, wherein the first input is directly coupled to a first output of a memory bit cell providing the first memory bit signal representing a value stored in a selected memory bit cell; and
receiving a second memory bit signal at the second input, wherein the second input is directly coupled to a second output of the memory bit cell providing the second memory bit signal that is a complement of the first memory bit signal.

12. The method of claim 9 further comprises:
amplifying the first input and the second input until a difference between the first input and the second input reaches a voltage required to reliably latch the differential input signal.

13. The method of claim 9 further comprises:
receiving a first memory bit signal through a bit switch circuit at the first input; and
receiving a complement of the first memory bit signal through the bit switch circuit at the second input, wherein the first memory bit signal and the complement of the first memory bit signal are shared by a group of selectable memory bit cells and provide a value stored in a selected memory bit cell when the differential amplifier is enabled.

14. A sense amplifier circuit for suppressing Miller effect bit line capacitive coupling, the sense amplifier circuit comprising:
a differential amplifier circuit having a true and complement differential input, a first output interstitial node, a second output interstitial node, an amplifier control input to enable or disable the differential amplifier and having an equalizer circuit coupled between the first output interstitial node and the second output interstitial node, wherein the Miller effect capacitive coupling is between the true and complement differential input and the first output interstitial node and the second output interstitial node; and
a cross coupled latch circuit having a latch first input, a latch first output, a latch second input, and a latch second output, the latch first input coupled to the first output interstitial node, the latch second input coupled to the second output interstitial node, wherein during a first time period the latch first output and the latch second output are precharged, the differential amplifier is disabled, and the equalizer circuit is enabled to suppress the Miller effect capacitive coupling prior to enabling the differential amplifier in a second time period.

15. The sense amplifier circuit of claim 14, wherein the true and complement differential input is directly coupled to a memory bit cell true and complement output of a word line selected memory bit cell.

16. The sense amplifier circuit of claim 14 wherein the second time period comprises amplifying the true and complement differential input to reliably latch the true and complement differential input in the cross coupled latch circuit.

17. The sense amplifier circuit of claim 14 wherein the equalizer circuit comprises:
a PMOS transistor with equalizer channel terminals coupled between the first output interstitial node and the second output interstitial node and with an equalizer gate input connected to a differential amplifier enable signal to enable the equalizer circuit while the differential amplifier circuit is disabled and to disable the equalizer circuit while the differential amplifier circuit is enabled.

18. The sense amplifier circuit of claim 14 wherein the equalizer circuit comprises:
an NMOS transistor with equalizer channel terminals coupled between the first output interstitial node and the second output interstitial node and with an equalizer gate input connected to an inverted differential amplifier enable signal to enable the equalizer circuit while the differential amplifier circuit is disabled and to disable the equalizer circuit while the differential amplifier circuit is enabled.

19. The sense amplifier circuit of claim 14, wherein the differential amplifier circuit comprises:
a first transistor with first channel terminals coupled between the first output interstitial node and a connection point and with a first control input coupled to the first input;
a second transistor with second channel terminals coupled between the second output interstitial node and the connection point and with a second control input coupled to the second input; and
a third transistor with third channel terminals coupled between the connection point and a first voltage and with a third control input connected to the differential amplifier enable signal.

20. The sense amplifier circuit of claim 14 wherein the cross coupled latch arrangement of four transistors comprises:
a first stack of two transistors having a latch first input, a first feedback input and a latch first output; and
a second stack of two transistors having a latch second input, a second feedback input and a latch second output;
wherein the latch first output is coupled to the second feedback input and the latch second output is coupled to the first feedback input; and
wherein each stack is coupled to a source voltage.
